(19) United States
(12) Patent Application Publication
(10) Pub. No.: US 2013/0000724 A1
(43) Pub. Date: Jan. 3, 2013

(54) METHOD OF MANUFACTURING GAS BARRIER FILM, AND GAS BARRIER FILM THUS MANUFACTURED

(75) Inventor: Shigehide Itou, Kanagawa (JP)

(73) Assignee: FUJIFILM CORPORATION, Tokyo (JP)

(21) Appl. No.: 13/636,028

(22) PCT Filed: Mar. 22, 2011
(86) PCT No.: PCT/JP2011/057517

§ 371 Date: Sep. 19, 2012

(30) Foreign Application Priority Data
Mar. 19, 2010 (JP) 2010-063954

(51) Int. Cl. B32B 7/02; B05D 3/12; H01L 31/0216

(52) U.S. Cl. 136/256; 428/217; 427/177

(57) ABSTRACT

Provided is a gas barrier film produced by according to a roll-to-roll process which is excellent in gas barrier performance. The gas barrier film is produced by providing, as a topmost layer on a second surface of the substrate film, a low-hardness layer having a pencil hardness lower by two or more grades than the pencil hardness of the organic layer; and providing the organic layer on the first surface of the substrate film.

### TECHNICAL FIELD

The present invention relates to a method of manufacturing a gas barrier film, and a gas barrier film thus manufactured.

### BACKGROUND ART

Manufacturing of gas barrier films according to a roll-to-roll process has been investigated. FIG. 5 is a schematic drawing illustrating a general method of manufacturing the gas barrier film according to the roll-to-roll process, in which a film is unwound from a rolled film 51, passes through a layer-forming apparatus 52 such as an inorganic layer forming apparatus, and is taken up on a roll 53. The roll-to-roll process may remarkably reduce labor and/or apparatus relevant to conveyance, since the film passes through the film-forming apparatus.

However, an organic/inorganic multi-layered gas barrier film having a high level of gas barrier performance has at least two layers formed on a substrate film, that are an organic layer and an inorganic layer which are necessarily dense in the texture thereof. Damage may, however, be anticipated in the manufacturing of the organic/inorganic multi-layered gas barrier film according to the roll-to-roll process, particularly in the process of taking-up on the roll. For example, Patent Document 1 discloses that a gas barrier film, having an anchor coating layer provided thereto, may be damaged in the anchor coating layer in the process of taking-up of the film, or may cause weaving in the process of forming a metal oxide film (inorganic layer) on the anchor coating layer (organic layer) by vacuum evaporation. Patent Document 1 also describes a method of solving the problem.

### PRIOR ART DOCUMENTS

### Patent Document

[Patent Document 1] JP-A-08-92727

### SUMMARY

### Problems to be Solved by the Invention

As described in the above, adoption of the roll-to-roll process may be desired in view of improving productivity of the gas barrier film. In particular, it is desired to provide the organic layer by coating, and to provide an inorganic layer by vacuum evaporation, according to the roll-to-roll process.

The present inventors, however, found from our investigations that the gas barrier film obtained by the method described in Patent Document 1 was still insufficient in an effect of reducing damage of the organic layer and the inorganic layer. Further investigations into Patent Document 1 by the present inventors revealed that Patent Document 1 has studied peeling of the anchor coating layer (organic layer) due to tight winding, and wrapping slippage which possibly occurs in the process of forming of the metal oxide film (inorganic layer), but has not studied damage possibly exerted on the substrate film at the second surface side (the surface opposite to the surface having the organic layer and the inorganic layer provided thereon).

The present invention is aimed at solving the problems, and is to provide a method of manufacturing a gas barrier film, according to the roll-to-roll process, capable of suppressing damages on the gas barrier film, and of improving the barrier performance.

### Means for Solving the Problems

The present inventors found out after our extensive investigations that, assuming the surface of the substrate film on which the organic layer is provided as a first surface and the opposite surface as a second surface, in the manufacturing of the gas barrier film according to the roll-to-roll process, a trial of taking up a substrate film having the organic layer formed on the first surface thereof, on a roll may damage the organic layer such as getting dent or scratch, due to contact with the second surface of the substrate film with the organic layer. More specifically, it was confirmed that, since the organic layer was damaged in the process of manufacturing the gas barrier film, so that the inorganic layer provided thereon could not be dense, and thereby the gas barrier performance of the gas barrier film degraded as a consequence. In view of ensuring a high level of gas barrier performance, it is therefore necessary to reduce damage on the organic layer possibly arisen from contact between the organic layer and the second surface of the substrate film. The present inventors then found out that the damage on the organic layer, ascribable to the contact with the second surface of the substrate film may be reduced by providing, on the second surface of the substrate film, a low-hardness layer having a pencil hardness lower by two or more grades than that of the organic layer, and completed the present invention.

[1] A method of manufacturing a gas barrier film comprising an organic layer and an inorganic layer on a first surface of a substrate film according to a roll-to-roll process, which comprises providing, as a topmost layer on a second surface of the substrate film, a low-hardness layer having a pencil hardness lower by two or more grades than the pencil hardness of the organic layer; and providing the organic layer on the first surface of the substrate film.
[2] The method of manufacturing a gas barrier film of [1], wherein the organic layer is provided after the low-hardness layer was provided.
[3] The method of manufacturing a gas barrier film of [1] or [2], wherein the low-hardness layer and the organic layer are continuously provided throughout a period over which the substrate film is unwound from one roll and taken up by another roll.
[4] The method of manufacturing a gas barrier film of any one of [1] to [3], wherein the low-hardness layer is removed after the organic layer was provided.
[5] The method of manufacturing a gas barrier film of [4], wherein the low-hardness layer is a peelable layer.
[6] The method of manufacturing a gas barrier film of any one of [1] to [5], wherein the inorganic layer is provided by vacuum evaporation.
[7] The method of manufacturing a gas barrier film of any one of [1] to [6], wherein the low-hardness layer and/or the organic layer are provided by coating.
[8] The method of manufacturing a gas barrier film of any one of [1] to [7], wherein the pencil hardness of the low-hardness layer is F or softer.
[9] The method of manufacturing a gas barrier film of any one of [1] to [7], wherein the pencil hardness of the low-hardness layer is 6B or softer.
[10] The method of manufacturing a gas barrier film of any one of [1] to [9], wherein the low-hardness layer is formed by applying a composition, containing latex and/or latex-crosslinked product, onto the substrate film.
[11] The method of manufacturing a gas barrier film of any one of [1] to [10], wherein the low-hardness layer contains polyethylene or polypropylene.
[12] The method of manufacturing a gas barrier film of any one of [1] to [11], wherein the organic layer is formed by applying a composition, containing at least one species selected from a (meth)acrylate, a latex, and a latex-crosslinked product, onto the substrate film.
[13] The method of manufacturing a gas barrier film of any one of [1] to [12], wherein the inorganic layer contains at least one species selected from silicon oxide, aluminum oxide, silicon nitride, aluminum nitride, silicon oxynitride and aluminum oxynitride.
[14] The method of manufacturing a gas barrier film of any one of [1] to [13], wherein the low-hardness layer has a glass transition temperature of 120° C. or lower.
[15] A gas barrier film comprising: an organic layer and an inorganic layer, provided on a first surface of a substrate film; and a low-hardness layer having a pencil hardness lower by two or more grades than the pencil hardness of the organic layer, provided as a topmost layer on a second surface of the substrate film, the low-hardness layer containing a resin having a glass transition temperature higher than 20° C., and containing substantially no particle.
[16] The gas barrier film of [15], wherein the pencil hardness of the low-hardness layer is F or softer.
[17] The gas barrier film of [15], wherein the pencil hardness of the low-hardness layer is 6B or softer.
[18] The gas barrier film of any one of [15] to [17], manufactured by the method described in any one of [1] to [14].
[19] An electronic device having the gas barrier film described in any one of [15] to [18].
[20] A solar cell back sheet or a solar cell device having the gas barrier film described in any one of [15] to [18].

### Effect of the Invention

By the present invention, the gas barrier film excellent in the gas barrier performance may be provided according to the roll-to-roll process.

### BRIEF DESCRIPTION OF THE DRAWING

FIG. 1 is a schematic drawing illustrating a layer configuration of a gas barrier film manufactured by the method of the present invention.

FIG. 2 is a schematic drawing illustrating an embodiment of the present invention.

FIG. 3 is a schematic drawing illustrating another layer configuration of the gas barrier film manufactured by the method of the present invention.

FIG. 4 is a schematic drawing illustrating a layer configuration of the film achieved midway in the process of manufacturing according to the method of the present invention.

FIG. 5 is a schematic drawing illustrating a general method of manufacturing the gas barrier film according to the roll-to-roll process.

### BEST MODES FOR CARRYING OUT THE INVENTION

The present invention will be detailed below. Note that expression of all numerical ranges using “to” in this patent specification mean the ranges covering the values placed before and after “to” as the lower and upper limit values, respectively.

The pencil hardness described in the present invention were measured conforming to JIS K-5600-5-4, wherein notations of hardness in decreasing order are 6H, 5H, 4H, 3H, 2H, H, F, HB, B, 2B, 3B, 4B, 5B and 6B. The films softer than 6B and harder than 6H were measured according to the same method, using 7B to 10B pencils, and 9H to 7H pencils, respectively, available from Mitsubishi Pencil Co., Ltd.

The method of manufacturing a gas barrier film of the present invention is such as manufacturing a gas barrier film, having an organic layer and an inorganic layer formed on a first surface of a substrate film, according to the roll-to-roll process. The method comprise providing, as a topmost layer on a second surface of the substrate film, a low-hardness layer having a pencil hardness lower by two or more grades than that of the organic layer; and providing the organic layer on the first surface of the substrate film. By ensuring a difference in pencil hardness of two or more grades between the organic layer and the low-hardness layer, the gas barrier film may be manufactured without causing any damage on the organic layer due to the second surface of the substrate film, even when the film is taken up in the process of manufacturing according to the roll-to-roll process.

The difference of pencil hardness herein is preferably three grades or larger, and more preferably four grades or larger. For example, “lower by two grades” means that the low-hardness layer has a pencil hardness of HB, as compared with the organic layer having a pencil hardness of H.

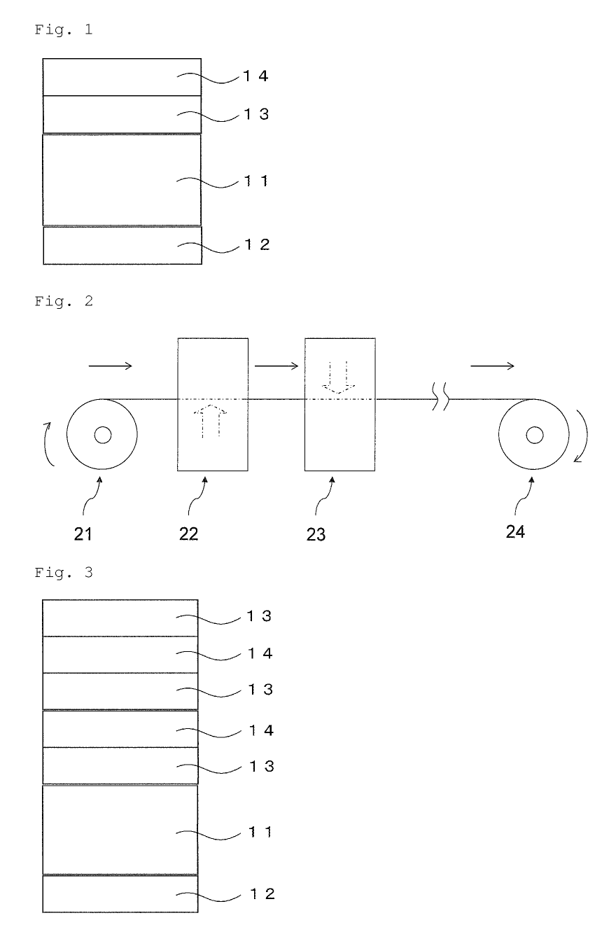

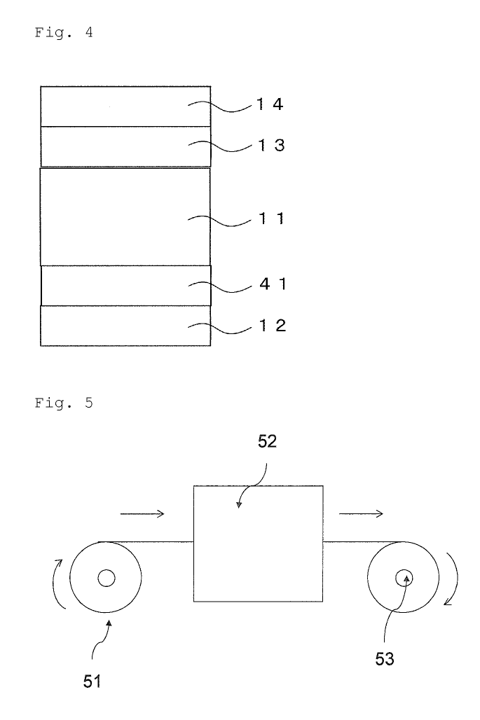

FIG. 1 is a schematic drawing illustrating the simplest layer configuration of the gas barrier film of the present invention, where reference numeral 11 stands for a substrate film, 12 for a low-hardness layer, 13 for an organic layer, and 14 for an inorganic layer. In the method of manufacturing a gas barrier film of this embodiment, it is preferable to provide organic layer 13 on the first surface of the substrate film, after the low-hardness layer 12 was provided on the second surface of the substrate film 11. By adopting such procedures, the organic layer may more effectively be prevented from being damaged by the second surface of the substrate film. In general, it is preferable to provide an inorganic layer 14, further on the surface of the organic layer 13.

In the present invention, it is preferable to continuously provide the low-hardness layer and the organic layer throughout a period over which the film is unwound from one roll and taken up by another roll. FIG. 2 is a schematic drawing illustrating a method of continuously providing the low-hardness layer and the organic layer throughout a period over which the film is unwound from one roll and taken up by another roll, wherein reference numeral 21 stands for a first roll, 22 for a low-hardness layer formation device, 23 for an organic layer formation device, and 24 for a second roll. In this embodiment, the substrate film unwound from the first roll is provided on the second surface thereof with the low-hardness layer during transit of the film through the low-hardness layer formation device 22, and then provided on the first surface thereof with the organic layer during transit of the film through the organic layer formation device 23. Thereafter, the film is taken up on the second roll 24. Alternatively in another embodiment, the inorganic layer may be further continuously provided before the film is taken up on the second roll 24.

In the manufacturing of the gas barrier film embodied as illustrated in FIG. 2, and for the case where the low-hardness layer needs drying in the process of formation thereof, it may be good enough that the low-hardness layer is dried before being taken up on the second roll even if the layer immediately after formed remains undried, so that even materials which take a long time for drying may readily be adoptable. Alternatively, for the case where both of the organic layer and the low-hardness layer need drying in the process of formation thereof, the drying of the both layers may be carried out at the same time. In this case, cost for the drying may be reduced. Still alternatively, for the case where a material which takes a relatively long time for drying is used for the organic layer, and a material which takes only a short time for drying is used for the low-hardness layer, the low-hardness layer may be provided after the organic layer was provided. In short, in this embodiment, it may be good enough that both of the low-hardness layer and the organic layer are provided in the period over which the substrate film is unwound from the first roll and taken up by the second roll.

In the present invention, a peelable layer may be adoptable to the low-hardness layer, and so that the method may include a process of removing the peelable layer. The peelable layer adoptable herein may be exemplified by a layer composed of a low-adhesive polymer or the like. The process of removing the peelable layer may be carried out at an appropriate point of time before completion of the final product. In particular, it is preferable to ship the products while leaving the peelable layer attached thereon, and to allow the user to remove the peelable layer before use. For an exemplary case where the gas barrier film of the present invention is adopted to a component for back sheet of solar cell, the peelable layer may be placed on the back surface of a PV module, and then may be removed. By adopting this sort of configuration, adhesion of dust and so forth may be suppressed.

The low-hardness layer in the present invention is preferably formed by applying a composition, which contains a material for forming the low-hardness layer and a solvent, onto the substrate film, and then by drying off the solvent. The low-hardness layer may further be cured typically by UV irradiation, if necessary.

While materials for composing the low-hardness layer are not specifically limited, so long as they may give a layer having a pencil hardness lower by two grades or more than that of the organic layer, they preferably have a pencil hardness of F or softer, more preferably have a pencil hardness of HB or softer, still more preferably have a pencil hardness of 6B or softer, and further more preferably have a pencil hardness of 6B to 10B. Adoption of this sort of materials may raise a tendency of remarkably improving the barrier performance. Materials adoptable to the low-hardness layer in the present invention are preferably resins having a glass transition temperature (Tg) of 20° C. or higher, and more preferably those having a Tg of 80° C. or higher. While the upper limit of Tg is not specifically limited, it is generally 120° C. or lower.

The low-hardness layer in the present invention is preferably formed by applying a composition, which contains a latex and/or latex-crosslinked product, onto the substrate film. The latex may be exemplified by polyester-base latex, styrene-butadiene-base latex, acrylonitrile-butadiene-base latex, acrylate-base latex, soap-free latex, fluorine-containing resin latex, polyolefin-base latex, siloxane-base latex, and acryl-siloxane-base latex.

The low-hardness layer in the present invention preferably contains one or more species selected from acrylate polymer, methacrylate polymer, epoxy resin, polyethylene, polyvinyl chloride, polypropylene, polystyrene, acrylonitrile (ABS resin), acrylonitrile-styrene copolymer (AS resin), polyacetal, polyimide, polycarbonate, modified polyphenylene ether (PPE), polybutylene terephthalate, polyallylate, polysulfone, polyphenylene sulfide, polyether ether ketone, polyimide resin and fluorine-containing resin, and preferably contains polyethylene or polypropylene.

While the low-hardness layer in the present invention may contain ingredients other than those described in the above, it is preferable that 95% by weight or more of the ingredient excluding the solvent that the composition used for forming the low-hardness layer, contains is the above-described materials, and/or 95% by weight or more of the ingredients composing the obtained low-hardness layer is the above ingredient. In particular, it is preferable that the low-hardness layer in the present invention contains substantially no particles. “Contains substantially no particles” herein means that the particles are not contained except for contaminants accidentally contained therein, and preferably means that the content amount of the particles of the low-hardness layer is 1% by weight or less. Such particles may be exemplified by matting agent.

While methods of applying the low-hardness layer onto the substrate film adoptable herein may be any publicly-known methods, general coating methods such as bar coating and reverse gravure coating may be preferable. By providing the low-hardness layer by coating, the productivity may further be improved.

While the thickness of the low-hardness layer is not specifically limited, it is preferably 1000 to 5000 nm.

The organic layer in the present invention is formed, preferably by applying a composition, which contains a material for composing the organic layer and a solvent, onto the substrate film, and then drying off the solvent. The organic layer is further cured typically by UV irradiation, if necessary.

While materials for composing the organic layer are not specifically limited so long as they may give a layer having a pencil hardness higher by two grades or more than that of the low-hardness layer, they preferably have a pencil hardness of harder than B, and more preferably in the range from HB to 2H.

Materials for composing the organic layer in the present invention may specifically be exemplified by a layer obtained by applying a (meth) acrylate-containing composition onto the substrate film, dried if necessary and then cured, and a layer obtained by applying a composition, which contains at least one species of latex and crosslinked product of latex, onto the substrate film.

While methods of applying the organic layer to the substrate film may be any publicly-known methods, general coating methods such as bar coating and reverse gravure coating may be preferable. By providing the low-hardness layer by coating, the productivity may further be improved.

While thickness of the organic layer is not specifically limited, it is preferably 500 nm to 1500 nm.

### Inorganic Layer

The inorganic layer in the present invention is preferably provided after the organic layer was provided. and more preferably provided directly on the surface of the organic layer. The inorganic layer is preferably provided by vacuum evaporation. By providing the inorganic layer by vacuum evaporation, the productivity may further be improved. Still more preferably, the inorganic layer is provided by electron-beam-heating vacuum evaporation. In the present invention, also the inorganic layer may preferably be provided using a vacuum evaporation apparatus based on the roll-to-roll process.

Material for composing the inorganic layer is preferably at least one species selected from silicon oxide, aluminum oxide, silicon nitride, aluminum nitride, silicon oxynitride and aluminum oxynitride, more preferably at least one species selected from silicon oxide, aluminum oxide and silicon nitride, and sill more preferably silicon oxide and/or aluminum oxide.

Thickness of the inorganic layer is preferably 50 to 150 nm.

### Substrate Film

The substrate film used in the present invention is not specifically limited, so long as it may be adoptable to the roll-to-roll process, and so far as it may support the organic layer, the inorganic layer, the low-hardness layer and so forth. In general, polyethylene terephthalate (PTE) and polyethylene naphthalate (PEN) may preferably be used.

Thickness of the substrate film is preferably 50 to 300 μm.

While the method of manufacturing a gas barrier film of the present invention, described in the above, disclosed the process of forming the low-hardness layer 12, one organic layer 13 and one inorganic layer 14 on the substrate film 11 as described in the above, the method may further include a process for providing other layer. In an illustrated example in FIG. 3, the low-hardness layer 12, the organic layer 13, and the inorganic layer 14 are provided on the substrate film 11, and thereafter, the organic layer 13, the inorganic layer 14, and the organic layer 13 are additionally provided in this order. Reference numerals in FIG. 3 are same as those in FIG. 1. The individual organic layers and the individual inorganic layers may be the same as, or different from each other, in their compositions, thickness and so forth. While the gas barrier film manufactured by the method of the present invention may successfully ensure an excellent level of gas barrier performance even with a single stack of one organic layer and one inorganic layer, a larger number of stacking may provide the gas barrier film having a higher level of barrier performance.

The method of manufacturing a gas barrier film of the present invention may further includes a process of forming other constitutive layers. For example, the method may include a process of providing other functional layer (s) on one surface or both surfaces of the substrate film, or a process of providing a protective layer as the topmost layer over the stack of the organic layer(s) and the inorganic layer(s). Such other functional layer may be exemplified by a matting agent-containing layer. The matting-agent-containing layer is preferably provided between the low-hardness layer and the substrate film. Adoption of this sort of configuration may raise a tendency of improving the conveyability.

The method of manufacturing a gas barrier film of the present invention may include a process of removing the low-hardness layer, after the organic layer was provided. This is because the low-hardness layer is aimed at suppressing damages on the organic layer in the process of manufacturing the gas barrier film, so that it may be preferable in some cases that the low-hardness layer is not contained in the gas barrier film as the final product. While methods of removing the low-hardness layer are not specifically limited, the low-hardness layer may be removed typically by preliminarily providing a peelable layer between the substrate film and the low-hardness layer, and then by lifting off the peelable layer.

FIG. 4 is a schematic drawing illustrating a layer configuration of the film achieved midway in the process of manufacturing according to the method of the present invention, which contains a process of forming the peelable layer. Reference numerals in FIG. 4 are same as those in FIG. 1. In this embodiment, the substrate film 11, a peelable layer 41, the low-hardness layer 12, the organic layer 13, and the inorganic layer 14 are provided in this order, wherein the low-hardness layer 12 may be removed by lifting off the peelable layer 41. By adopting this sort of configuration, the gas barrier film having excellent in the barrier performance may be manufactured, without leaving the unnecessary layer in the final product. Alternatively, it may be also allowable to provide the organic layer, then to lift off the peelable layer 41 to thereby remove the low-hardness layer 12, and then to provide the inorganic layer 14. Still another possible embodiment may be such as shipping the gas barrier film with the peelable layer unremoved, and allowing the user to remove peelable layer before use.

The present invention also discloses a gas barrier film manufactured by the method of the present invention. The gas barrier film may typically be configured to have an organic layer and an inorganic layer, provided on a first surface of a substrate film; and a low-hardness layer having a pencil hardness lower by two or more grades than that of the organic layer, provided as a topmost layer on a second surface of the substrate film. The low-hardness layer contains a resin having a glass transition temperature higher than 20° C., and contains substantially no particle. Details of the substrate film, the organic layer, the inorganic layer and the low-hardness layer may be referred to the description in the above.

### (Solar Cell)

The gas barrier film of the present invention is preferably used for a back sheet for a solar cell or a solar cell device.

The back sheet for a solar cell of the present invention is used for a solar cell. The solar cell device generally comprises an active part which operates as the solar cell, provided between a pair of substrates, and the back sheet for a solar cell of the present invention is used for the substrate at the back sheet side.

The solar cell devices preferably applicable to the back sheet of the invention are not specifically limited. For example, they include single crystal silicon-based solar cell devices, polycrystalline silicon-based solar cell devices, single-junction or tandem-structure amorphous silicon-based solar cell devices, gallium-arsenic (GaAs), indium-phosphorus (InP) or the like III-V Group compound semiconductor-based solar cell devices, cadmium-tellurium (CdTe) or the like II-VI Group compound semiconductor-based solar cell devices, copper/indium/selenium (CIS-based), copper/indium/gallium/selenium (CIGS-based), copper/indium/gallium/selenium/sulfur (CIGSS-based) or the like I-III-VI Group compound semiconductor-based solar cell devices, dye-sensitized solar cell devices, organic solar cell devices, etc. Above all, in the invention, the solar cell devices are preferably copper/indium/selenium (CIS-based), copper/indium/gallium/selenium (CIGS-based), copper/indium/gallium/selenium/sulfur (CIGSS-based) or the like I-III-VI Group compound semiconductor-based solar cell devices.

The description in JP-A-2009-38236 may be referred in the present invention as long as it deviates from the scope of the invention.

### [Electronic Device]

The gas barrier film of the present invention may be favorably used for electronic devices other than the solar cell.

Examples of the electronic devices include organic electroluminescence devices, liquid crystal display devices, thin-film transistors, touch panels, and electronic papers.

### [Organic Electroluminescence Device]

Examples of the organic electroluminescence device having a gas barrier film are disclosed in JP-A-2007-30387.

### [Liquid Crystal Display Device]

Examples of the liquid crystal display device are disclosed in JP-A-2009-172993, at paragraph 0044.

### (Others)

Other applications of the invention are thin-film transistors as in JP-T H10-512104, touch panels as in JP-A 5-127822, 2002-48913, and electronic papers as in JP-A-2000-98326.

### EXAMPLES

The characteristics of the invention are described more concretely with reference to the following Examples. In the following Examples, the material used, its amount and the ratio, the details of the treatment and the treatment process may be suitably modified or changed not overstepping the sprit and the scope of the invention. Accordingly, the invention should not be limitatively interpreted by the Examples mentioned below.

### <Formation of Gas Barrier Film>

### Example 1

On one surface of a polyethylene terephthalate (PET) film (Lumilar S10, from TORAY Industries, Inc., 100 μm thick), a coating liquid prepared by adding 0.5% by weight of a photoinitiator for UV curing (Esacure KTO46, from Lamberti) to a methyl ethyl ketone (MEK) solution of 7.5% by weight of ethylene oxide-modified trimethylolpropane triacrylate (Alonix M360, from TOAGOSEI Co., Ltd.) was coated, the solvent was removed by drying, and the coating was cured by UV irradiation. Succeedingly, on the surface opposite to the above-described coated surface, a coating liquid prepared by adding 0.5% by weight of a photoinitiator for UV curing (Esacure KTO46, from Lamberti) to a MEK solution of 7.5% by weight of trimethylolpropane triacrylate (Alonix M309, from TOAGOSEI Co., Ltd.) was coated, the solvent was removed by drying, the coating was cured by UV irradiation, and the film was taken up on a roll. The taken-up film was set on a roll-to-roll-type vacuum evaporation apparatus, a SiO film was continuously formed over the surface of the trimethylolpropane triacrylate polymer film by RF induction heating vacuum evaporation, and the film was taken up on a roll.

### Example 2

On one surface of a PET film (Lumilar S10, from TORAY Industries, Inc., 100 μm thick), a water-based dispersion (10% by weight) of polyester-base latex (Vylonal MD1480, from TOYOBO Co., Ltd.) was coated, and the coating was dried under heating to form a film. On the surface opposite to the above-described coated surface, a coating liquid prepared by adding 0.5% by weight of a photoinitiator for UV curing (Esacure KTO46, from Lamberti) to a MEK solution of 7.5% by weight of trimethylolpropane triacrylate (Alonix M309, from TOAGOSEI Co., Ltd.) was coated by bar coating, the solvent was removed by drying, the coating was cured by UV irradiation, and the film was taken up on a roll. The taken-up film was then set on a roll-to-roll-type vacuum evaporation apparatus, and a SiO film was continuously formed over the surface of the trimethylolpropane triacrylate polymer film by RF induction heating vacuum evaporation, and the film was taken up on a roll.

### Example 3

On one surface of the a PET film (Lumilar S10, from TORAY Industries, Inc., 100 μm thick), having on the opposite surface thereof a tacky polypropylene film (Hitalex DP1010, from Hitachi Chemical Co., Ltd., 50 μm thick) preliminarily bonded, a water-based dispersion (having a solid content of 10% by weight) of a polyester-base latex (Vylonal MD1480, from TOYOBO Co., Ltd.) was coated, the coating was dried under heating to form a film, and the film was taken up on a roll. The taken-up film was then set on a roll-to-roll-type vacuum evaporation apparatus, and a SiO film was continuously formed over the surface of the polyester-base latex film by RF induction heating vacuum evaporation, and the film was taken up on a roll.

The obtained polypropylene film was found to be peelable without difficulty.

### Comparative Example 1

On one surface of a PET film (Lumilar S10, from TORAY Industries, Inc., 100 μm thick), a coating liquid prepared by adding 0.5% by weight of a photoinitiator for UV curing (Esacure KTO46, from Lamberti) to a methyl ethyl ketone (MEK) solution of 7.5% by weight of trimethylolpropane triacrylate (Alonix M309, from TOAGOSEI Co., Ltd.) was coated, the solvent was removed by drying, and the coating was cured by UV irradiation. Succeedingly, on the surface opposite to the above-described coated surface, a coating liquid prepared by adding 0.5% by weight of a photoinitiator for UV curing (Esacure KTO46, from Lamberti) to a MEK solution of 7.5% by weight of ethylene oxide-modified trimethylolpropane triacrylate (Alonix M360, from TOAGOSEI Co., Ltd.) was coated, the solvent was removed by drying, the coating was cured by UV irradiation, and the film was taken up on a roll. The taken-up film was then set on a roll-to-roll-type vacuum evaporation apparatus, and a SiO film was continuously formed over the surface of the ethylene oxide-modified trimethylolpropane triacrylate polymer film by RF induction heating vacuum evaporation, and the film was taken up on a roll.

### Comparative Example 2

On one surface of a PET film (Lumilar S10, from TORAY Industries, Inc., 100 μm thick), a water-based dispersion (10% by weight) of a polyester-base latex (Vylonal MD1480, from TOYOBO Co., Ltd.) was coated, and the coating was dried under heating to form a film. On the surface opposite to the above-described coated surface, a coating liquid prepared by adding 0.5% by weight of a photoinitiator for UV curing (Esacure KTO46, from Lamberti) to a MEK solution of 7.5% by weight of trimethylolpropane triacrylate (Alonix M309, from TOAGOSEI Co., Ltd.) was coated, the solvent was removed by drying, the coating was cured by UV irradiation, and the film was taken up on a roll. The taken-up film was then set on a roll-to-roll-type vacuum evaporation apparatus, and a SiO film was continuously formed over the surface of the polyester-base latex film by RF induction heating vacuum evaporation, and the film was taken up on a roll.

### Comparative Example 3

On one surface of a PET film (Lumilar S10, from TORAY Industries, Inc., 100 μm thick), a water-based dispersion (10% by weight) of a polyester-base latex (Vylonal MD1480, from TOYOBO Co., Ltd.) was coated, and the coating was dried under heating to form a film. On the surface opposite to the above-described coated surface, a coating liquid prepared by adding 0.5% by weight of a photoinitiator for UV curing (Esacure KTO46, from Lamberti) to a MEK solution of 7.5% by weight of ethylene oxide-modified trimethylolpropane triacrylate (Alonix M360, from TOAGOSEI Co., Ltd.) was coated, the solvent was removed by drying, the coating was cured by UV irradiation, and the film was taken up on a roll. The taken-up film was then set on a roll-to-roll-type vacuum evaporation apparatus, and a SiO film was continuously formed over the surface of the polyester-base latex film by RF induction heating vacuum evaporation, and the film was taken up on a roll.

### Comparative Example 4

On one surface of a PET film (Lumilar S10, from TORAY Industries, Inc., 100 μm thick), a coating liquid prepared by adding 0.5% by weight of a photoinitiator for UV curing (Esacure KTO46, from Lamberti) to a MEK solution of 7.5% by weight of trimethylolpropane triacrylate (Alonix M309, from TOAGOSEI Co., Ltd.) was coated, the solvent was removed by drying, and the coating was cured by UV irradiation. Succeedingly, on the surface opposite to the above-described coated surface, a coating liquid prepared by adding 0.5% by weight of a photoinitiator for UV curing (Esacure KTO46, from Lamberti) to a MEK solution of 7.5% by weight of trimethylolpropane triacrylate (Alonix M309, from TOAGOSEI Co., Ltd.) was coated, the solvent was removed by drying, the coating was cured by UV irradiation, and the film was taken up on a roll. The taken-up film was then set on a roll-to-roll-type vacuum evaporation apparatus, and a SiO film was continuously formed over the surface of the trimethylolpropane triacrylate polymer film on one side by RF induction heating vacuum evaporation, and the film was taken up on a roll.

### Comparative Example 5

On one surface of a PET film (Lumilar S10, from TORAY Industries, Inc., 100 μm thick), a coating liquid prepared by adding 0.5% by weight of a photoinitiator for UV curing (Esacure KTO46, from Lamberti) to a MEK solution of 7.5% by weight of ethylene oxide-modified trimethylolpropane triacrylate (Alonix M360, from TOAGOSEI Co., Ltd.) was coated, the solvent was removed by drying, and the coating was cured by UV irradiation. Succeedingly, on the surface opposite to the above-described coated surface, a water-based dispersion (10% by weight) of a polyester-base latex (Vylonal MD1480, from TOYOBO Co., Ltd.) was coated, the coating was dried under heating to form a film, and the film was taken up on a roll. The taken-up film was then set on a roll-to-roll-type vacuum evaporation apparatus, and a SiO film was continuously formed over the surface of the ethylene oxide-modified trimethylolpropane triacrylate polymer film by RF induction heating vacuum evaporation, and the film was taken up on a roll.

### Example 4

On one surface of a PET film (Lumilar S10, from TORAY Industries, Inc., 100 μm thick), a coating liquid prepared by adding 0.5% by weight of a photoinitiator for UV curing (Esacure KTO46, from Lamberti) to a MEK solution of 7.5% by weight of urethane acrylate (UV7600B, from DAICEL-CYTEC Co., Ltd.) was coated, the solvent was removed by drying, and the coating was cured by UV irradiation. Succeedingly, on the surface opposite to the above-described coated surface, a coating liquid prepared by adding 0.5% by weight of a photoinitiator for UV curing (Esacure KTO46, from Lamberti) to a MEK solution of 7.5% by weight of trimethylolpropane triacrylate (Alonix M309, from TOAGOSEI Co., Ltd.) was coated, the solvent was removed by drying, the coating was cured by UV irradiation, and the film was taken up on a roll. The taken-up film was then set on a roll-to-roll-type vacuum evaporation apparatus, and a SiO film was continuously formed over the surface of the urethane acrylate polymer film by RF induction heating vacuum evaporation, and the film was taken up on a roll.

### Example 5

A gas barrier film was formed according to the same method as that in Example 1, except that the roll-to-roll-type vacuum evaporation apparatus was replaced with roll- to roll-type vacuum sputtering apparatus, and an oxidized aluminum film was continuously formed over the surface of the trimethylolpropane triacrylate polymer film by reactive sputtering method.

### Example 6

A gas barrier film was formed according to the same method as that in Example 1, except that the roll-to-roll-type vacuum evaporation apparatus was replaced with roll- to roll-type vacuum sputtering apparatus, and a SiO₂ film was continuously formed over the surface of the trimethylolpropane triacrylate polymer film by reactive sputtering method.

### Example 7

A gas barrier film was formed according to the same method as that in Example 1, except that the roll-to-roll-type vacuum evaporation apparatus was replaced with roll- to roll-type CVD apparatus, and a silicone nitride film was continuously formed over the surface of the trimethylolpropane triacrylate polymer film.

### Example 8

A gas barrier film was formed according to the same method as that in Example 1, except that the roll-to-roll-type vacuum evaporation apparatus was replaced with roll- to roll-type CVD apparatus, and a silicon nitride-oxide film was continuously formed over the surface of the trimethylolpropane triacrylate polymer film.

### <Evaluation>

The obtained gas barrier films were evaluated in terms of hardness and barrier performance (water vapor transmission rate).

### (Hardness)

Pencil hardness of the organic layer and the low-hardness layer was measured conforming to a method described in JIS K-5600-5-4.

### (Water Vapor Transmission Rate (WVTR))

Barrier performance of the gas barrier films against water vapor was measured by the calcium corrosion test at 40° C., 90% RH (relative humidity). Results were expressed by the criteria below:

⊚: WVTR≦0.005 g/m²·day
∘: 0.005 g/m²·day<WVTR≦0.05 g/m²·day
Δ: 0.05 g/m²·day<WVTR≦0.1 g/m²·day
x: 0.1 g/m²·day<WVTR

Results are shown in Table below.

TABLE 1

| | Organic layer | | Low-hardness layer | | |
|---|---|---|---|---|---|
| | | Pencil | | Pencil | Barrier |
| | Material | hardness | Material | hardness | performance |
| Example 1 | M309 | 2H | M360 | F | ◯ |
| Example 2 | M309 | 2H | MD1480 | HB | ◯ |
| Example 3 | MD1480 | HB | DP1010 | 6B | ⊚ |
| Comp. | M360 | F | M309 | 2H | X |
| Example 1 | | | | | |
| Comp. | MD1480 | HB | M309 | 2H | X |
| Example 2 | | | | | |
| Comp. | MD1480 | HB | M360 | F | X |
| Example 3 | | | | | |
| Comp. | M309 | 2H | M309 | 2H | X |
| Example 4 | | | | | |
| Comp. | M360 | F | MD1480 | HB | X |
| Example 5 | | | | | |
| Example 4 | UV7600B | 4H | M309 | 2H | Δ |

TABLE 2

| | | | Low-hardness | | | |
|---|---|---|---|---|---|---|
| | Organic layer | | layer | | | |
| | | Pencil | | Pencil | Inorganic | Barrier |
| | Material | hardness | Material | hardness | layer | performance |
| Example 5 | M309 | 2 H | M360 | F | oxidized | ⊚ |
| | | | | | aluminum | |
| Example 6 | M309 | 2 H | M360 | F | SiO₂ | ◯ |
| Example 7 | M309 | 2 H | M360 | F | silicone | ⊚ |
| | | | | | nitride | |
| Example 8 | M309 | 2 H | M360 | F | silicone | ◯ |
| | | | | | nitride-oxide | |

As is obvious from the Table, the gas barrier films excellent in the barrier performance were obtained by setting the pencil hardness of the low-hardness layer lower by two or more grades than that of the organic layer. In contrast, it was confirmed that the barrier performance was considerably degraded when pencil hardness of the low-hardness layer was higher than that of the organic layer. In particular, the method of manufacturing of the present invention was proven to produce the gas barrier films having barrier performance represented by values of 0.1 g/m² or smaller, with a high productivity. In addition, as is clear from Examples 5 to 8, the gas barrier films of the present invention exert extremely excellent barrier performance regardless of the kinds of the inorganic layer.

It was also found from Example 3 that the barrier performance was remarkably improved, by adopting the low-hardness layer having a pencil hardness of 6B or lower.

The method of manufacturing of the present invention is very useful from the viewpoint that the gas barrier film, having a barrier performance represented by a value of 0.1 g/m² or smaller, may be obtained even if the organic layer is provided by coating, and the inorganic layer is provided by vacuum evaporation, according to the roll-to-roll process.

It was also found that the gas barrier film, having a barrier performance represented by a value of 0.1 g/m² or smaller, was obtained only by a single stack of one organic layer and one inorganic layer.

The present disclosure relates to the subject matter contained in Japanese Patent Application No. 063954/2010 filed on Mar. 19, 2010, which is expressly incorporated herein by reference in their entirety. All the publications referred to in the present specification are also expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

1. A method of manufacturing a gas barrier film comprising an organic layer and an inorganic layer on a first surface of a substrate film according to a roll-to-roll process, which comprises
providing, as a topmost layer on a second surface of the substrate film, a low-hardness layer having a pencil hardness lower by two or more grades than the pencil hardness of the organic layer; and
providing the organic layer on the first surface of the substrate film.

2. The method of manufacturing a gas barrier film of claim 1, wherein the organic layer is provided after the low-hardness layer was provided.

3. The method of manufacturing a gas barrier film of claim 1, wherein the low-hardness layer and the organic layer are continuously provided throughout a period over which the substrate film is unwound from one roll and taken up by another roll.

4. The method of manufacturing a gas barrier film of claim 1, wherein the low-hardness layer is removed after the organic layer was provided.

5. The method of manufacturing a gas barrier film of claim 4, wherein the low-hardness layer is a peelable layer.

6. The method of manufacturing a gas barrier film of claim 1, wherein the inorganic layer is provided by vacuum evaporation.

7. The method of manufacturing a gas barrier film of claim 1, wherein the low-hardness layer and/or the organic layer are provided by coating.

8. The method of manufacturing a gas barrier film of claim 1, wherein the pencil hardness of the low-hardness layer is F or softer.

9. The method of manufacturing a gas barrier film of claim 1, wherein the pencil hardness of the low-hardness layer is 6B or softer.

10. The method of manufacturing a gas barrier film of claim 1, wherein the low-hardness layer is formed by applying a composition, containing latex and/or latex-crosslinked product, onto the substrate film.

11. The method of manufacturing a gas barrier film of claim 1, wherein the low-hardness layer contains polyethylene or polypropylene.

12. The method of manufacturing a gas barrier film of claim 1, wherein the organic layer is formed by applying a composition, containing at least one species selected from a (meth)acrylate, a latex, and a latex-crosslinked product, onto the substrate film.

13. The method of manufacturing a gas barrier film of claim 1, wherein the inorganic layer contains at least one species selected from silicon oxide, aluminum oxide, silicon nitride, aluminum nitride, silicon oxynitride and aluminum oxynitride.

14. The method of manufacturing a gas barrier film of claim 1, wherein the low-hardness layer has a glass transition temperature of 120° C. or lower.

15. A gas barrier film comprising:
an organic layer and an inorganic layer, provided on a first surface of a substrate film; and
a low-hardness layer having a pencil hardness lower by two or more grades than the pencil hardness of the organic layer, provided as a topmost layer on a second surface of the substrate film,
the low-hardness layer containing a resin having a glass transition temperature higher than 20° C., and containing substantially no particle.

16. The gas barrier film of claim 15, wherein the pencil hardness of the low-hardness layer is F or softer.

17. The gas barrier film of claim 15, wherein the pencil hardness of the low-hardness layer is 6B or softer.

18. A gas barrier film comprising an organic layer and an inorganic layer on a first surface of a substrate film, which is produced by a roll-to-roll process comprising:
providing, as a topmost layer on a second surface of the substrate film, a low-hardness layer having a pencil hardness lower by two or more grades than the pencil hardness of the organic layer; and
providing the organic layer on the first surface of the substrate film.

19. An electronic device having a gas barrier film comprising an organic layer and an inorganic layer on a first surface of a substrate film, which is produced by a roll-to-roll process comprising:
providing, as a topmost layer on a second surface of the substrate film, a low-hardness layer having a pencil hardness lower by two or more grades than the pencil hardness of the organic layer; and
providing the organic layer on the first surface of the substrate film.

20. A solar cell back sheet or a solar cell device having a gas barrier film comprising an organic layer and an inorganic layer on a first surface of a substrate film, which is produced by a roll-to-roll process comprising:
providing, as a topmost layer on a second surface of the substrate film, a low-hardness layer having a pencil hardness lower by two or more grades than the pencil hardness of the organic layer; and
providing the organic layer on the first surface of the substrate film.
